(19) United States
(12) Patent Application Publication
(10) Pub. No.: US 2026/0153673 A1
(43) Pub. Date: Jun. 4, 2026

(54) SEMICONDUCTOR PACKAGE

(71) Applicant: Samsung Electronics Co., Ltd., Suwon-si (KR)

(72) Inventors: Hyeonjeong HWANG, Suwon-si (KR); Junghoon KANG, Suwon-si (KR)

(73) Assignee: Samsung Electronics Co., Ltd., Suwon-si (KR)

(21) Appl. No.: 19/247,522

(22) Filed: Jun. 24, 2025

(30) Foreign Application Priority Data
Nov. 29, 2024 (KR) 10-2024-0175173

(51) Int. Cl. G02B 6/122; G02B 6/12; H01L 23/498; H01L 25/16

(52) U.S. Cl. CPC G02B 6/1228; H10W 70/65; H10W 90/00; H10W 90/701; G02B 2006/12038

(57) ABSTRACT

A semiconductor package includes a substrate including a first surface and a second surface opposite to the first surface, a waveguide buried in the substrate, an optical integrated circuit mounted on the first surface of the substrate and optically connected to the waveguide, an electronic integrated circuit mounted on the first surface of the substrate and electrically connected to the optical integrated circuit, and a semiconductor chip disposed on the second surface of the substrate.

### CROSS-REFERENCE TO RELATED APPLICATION

This application claims priority to and the benefit of Korean Patent Application No. 10-2024-0175173 filed at the Korean Intellectual Property Office on Nov. 29, 2024, the entire contents of which are incorporated herein by reference.

### BACKGROUND

### 1. Field

The present disclosure relates to semiconductor packages.

### 2. Description of the Related Art

A silicon photonics technology is the only solution that may deal with exponentially increasing intra/inter data center traffic and/or telecom traffic with low photonic propagation loss (or low optical propagation loss), lower power consumption, higher bandwidth, and/or mature commercial complementary metal-oxide-semiconductor (CMOS) process compatibility. A silicon photonics-based photonic integrated circuit (PIC) technology integrates various photonic elements on one chip to significantly reduce cost and/or size of manufacturing and/or packaging.

A silicon photonics-based PIC may be monolithically integrated into a single chip with an electronic integrated circuit (EIC). Accordingly, a conventional three-dimensional integration structure in which an EIC chip (or an application-specific integrated circuit (ASIC) chip) is flip-chip bonded to a silicon photonics-based PIC chip may flip-chip bond the EIC chip (or the ASIC chip) and the PIC chip through a solder bump without a relatively long bonding wire to have an advantage in which a relatively high-speed electrical signal propagates a relatively short distance so that loss is relatively small.

### SUMMARY

According to some example embodiments, reliability and/or degree of integration of a semiconductor package may be improved.

A semiconductor package according to an example embodiment of the present disclosure includes a substrate including a first surface and a second surface opposite to the first surface, a waveguide buried in the substrate, an optical integrated circuit on the first surface of the substrate, the optical integrated circuit optically connected to the waveguide, an electronic integrated circuit on the first surface of the substrate, the electronic integrated circuit electrically connected to the optical integrated circuit, and a semiconductor chip disposed on the second surface of the substrate.

A semiconductor package according to another example embodiment includes a substrate including a first surface and a second surface opposite to the first surface, the substrate including a first material, an interconnector on a side surface of the substrate, a waveguide buried in the substrate adjacent to the first surface, the waveguide optically connected to the interconnector, the waveguide including the first material; an optical integrated circuit on the first surface of the substrate, the optical integrated circuit optically connected to the waveguide, an electronic integrated circuit on the first surface of the substrate, the electronic integrated circuit electrically connected to the optical integrated circuit, and a semiconductor chip on the second surface of the substrate, wherein a concentration of the first material of the waveguide is less than a concentration of the first material of the substrate.

A semiconductor package according to another example embodiment includes a substrate including a first surface and a second surface opposite to the first surface, an interconnector on a side surface of the substrate, a waveguide buried in the substrate adjacent to the first surface, the waveguide optically connected to the interconnector, an optical integrated circuit on the first surface of the substrate, the optical integrated circuit optically connected to the waveguide, an electronic integrated circuit on the first surface of the substrate, the electronic integrated circuit electrically connected to the optical integrated circuit, a redistribution structure on the second surface of the substrate, a semiconductor chip on the redistribution structure, and a memory chip on the redistribution structure, is the memory chip electrically connected to the semiconductor chip, wherein the waveguide overlaps the optical integrated circuit in a vertical direction, and the electronic integrated circuit overlaps the semiconductor chip in the vertical direction.

A method of manufacturing a semiconductor package according to an example embodiment includes providing a preliminary substrate including a first surface and a second surface opposite to the first surface, forming a conductive post within the preliminary substrate such that a first end of the conductive post is exposed by the second surface and a second end of the conductive post is vertically adjacent to the first surface, forming a redistribution structure on the second surface, removing a portion of the preliminary substrate from the first surface to expose the second end of the conductive post, forming a waveguide to be buried in the substrate adjacent to the first surface, forming a first interconnection structure in a portion of the substrate including the first surface, forming a conductive pillar on the first surface, forming a solder on the conductive pillar, forming an optical integrated circuit and an electronic integrated circuit on the first surface, forming a semiconductor chip and a memory chip to be spaced apart from each other on an exposed surface of the redistribution structure.

The forming a waveguide may include forming a mask pattern including an opening on the first surface of the preliminary substrate, replacing a first material present in a portion of the substrate with a second material using an ion exchange method to form a preliminary waveguide, removing the mask pattern, and replacing back the second material present in at least a portion of the preliminary waveguide with the first material using an ion exchange method to form the waveguide.

The method may further include forming an interconnector on a side surface of the waveguide.

According to some example embodiments, reliability and/or degree of integration of a semiconductor package may be improved.

### BRIEF DESCRIPTION OF THE DRAWINGS

FIG. 1 is a cross-sectional view showing a semiconductor package according to an example embodiment.

FIG. 2 is an enlarged cross-sectional view of an area S1 of FIG. 1.

FIG. 3 is a cross-sectional view showing a waveguide of the semiconductor package according to an example embodiment.

FIG. 4 is a schematic block diagram showing components of a semiconductor package according to an example embodiment.

FIG. 5 is a cross-sectional view showing an optical integrated circuit of a semiconductor package according to an example embodiment.

FIG. 6 is a cross-sectional view showing a semiconductor package according to an example embodiment and corresponding to the area S1 of FIG. 1.

FIG. 7 is a plan view showing a waveguide of the semiconductor package according to the example embodiment of FIG. 6.

FIG. 8 is a cross-sectional view showing a semiconductor package according to an example embodiment and corresponding to the area S1 of FIG. 1.

FIGS. 9 to 11 are cross-sectional views showing semiconductor packages according to some example embodiments.

FIGS. 12 to 21 are cross-sectional views showing a manufacturing method of the semiconductor package according to an example embodiment.

### DETAILED DESCRIPTION

Some example embodiments of the present disclosure will be described more fully hereinafter with reference to the accompanying drawings so that those skilled in the art could easily implement the example embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, each element's size and thickness are arbitrarily illustrated for ease of description, but the present disclosure is not necessarily limited to those illustrated in the drawings.

Throughout the specification, when a part is “connected” to another part, it includes not only a case where the part is “directly connected” but also a case where the part is “indirectly connected” with another part in between. Unless explicitly stated to the contrary, the word “comprise” and variations such as “comprises” and “comprising” should be understood to imply the inclusion of stated elements but not the exclusion of any other elements.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side surface of the referenced part based on a gravitational direction.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

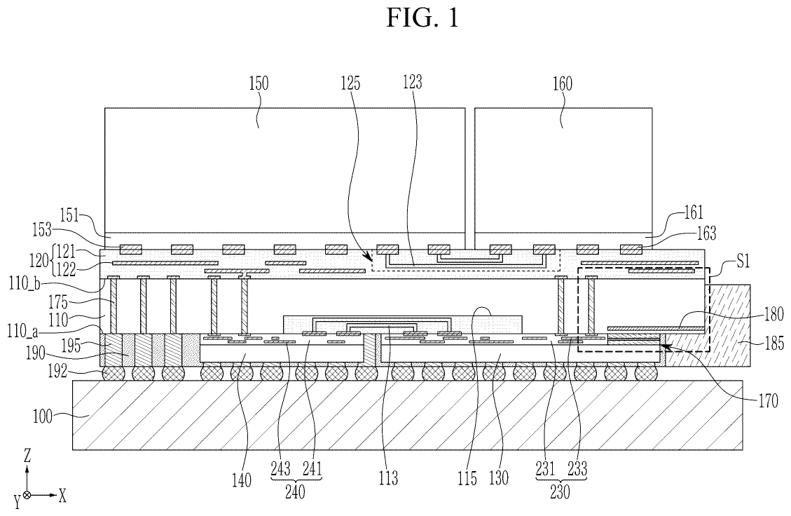

Hereinafter, a semiconductor package device according to an example embodiment will be described with reference to FIGS. 1 to 3.

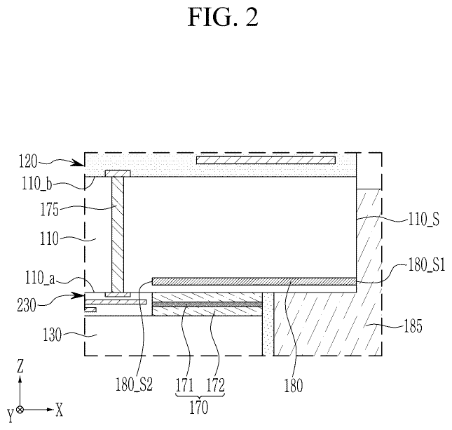

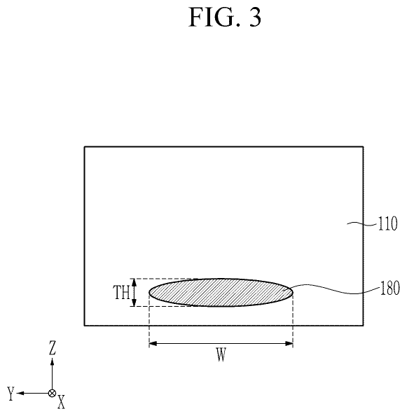

FIG. 1 is a cross-sectional view showing the semiconductor package according to the example embodiment. FIG. 2 is an enlarged cross-sectional view of an area S1 of FIG. 1. FIG. 3 is a cross-sectional view showing a waveguide of the semiconductor package according to an example embodiment.

The semiconductor package according to the example embodiment may include a substrate 110 including a first surface 110_a and a second surface 110_b, a waveguide 180 buried (or embedded) in the substrate 110, an optical integrated circuit 130 disposed on the first surface 110_a of the substrate 110, an electronic integrated circuit 140 disposed on the first surface 110_a of the substrate 110, and a semiconductor chip 150 disposed on the second surface 110_b of the substrate 110. The semiconductor package according to the example embodiment may be a photonics semiconductor package.

The substrate 110 may be a glass substrate. The substrate 110 may include silica. For example, the substrate 110 may include a silicon-based material such as glass or silicon oxide, an organic material, another material such as aluminum oxide, or any combination of these materials. In an example embodiment, the substrate 110 may include a first material. For example, the first material may be a sodium ion (Na⁺), but example embodiments of the present disclosure are not limited thereto. That is, the substrate 110 may be the glass substrate including the sodium ion (Na⁺). The substrate 110 may include one or more routing wires. In an example embodiment, if the substrate 110 is made of the glass substrate including the first material, a refractive index of the substrate 110 may be about 1.44 to about 1.46, but example embodiments of the present disclosure are not limited thereto. In some example embodiments, the substrate 110 may further include a second material different from the first material, but example embodiments of the present disclosure are not limited thereto. The second material may include a silver ion (Ag⁺) or a potassium ion (K⁺).

The substrate 110 may include the first surface 110_a and the second surface 110_b that are opposite to each other. The first surface 110_a and the second surface 110_b of the substrate 110 may be formed of a plane parallel to a first direction (e.g., an X direction) and a second direction (e.g., a Y direction) intersecting the first direction (the X direction). The first surface 110_a of the substrate 110 may be a surface opposite to the second surface 110_b in a third direction (e.g., a Z direction). The first surface 110_a of the substrate 110 may be referred to as a lower surface of the substrate 110, and the second surface 110_b of the substrate 110 may be referred to as an upper surface of the substrate 110. The third direction (the Z direction) may mean a vertical direction that is perpendicular to the first surface 110_a of the substrate 110.

The waveguide 180 may be buried in the substrate 110. For example, the waveguide 180 may be buried in the first surface 110_a of the substrate 110 (e.g., in the substrate 110 adjacent to the first surface 110_a). The waveguide 180 may be surrounded by (or embedded in) the substrate 110. Accordingly, a lower surface of the waveguide 180 may be disposed at a higher level than that of the first surface 110_a of the substrate 110. The lower surface of the waveguide 180 may be disposed closer to a lower surface of a redistribution structure 120 than to the first surface 110_a of the substrate 110.

In an example embodiment, the waveguide 180 may extend in one direction. For example, as illustrated in FIG. 2, the waveguide 180 may extend in the first direction (the X direction) from a side surface 110_S of the substrate 110. In this case, a length along the first direction (the X direction) of the waveguide 180 may be about 50 μm to about 100 μm, but example embodiments of the present disclosure are not limited thereto.

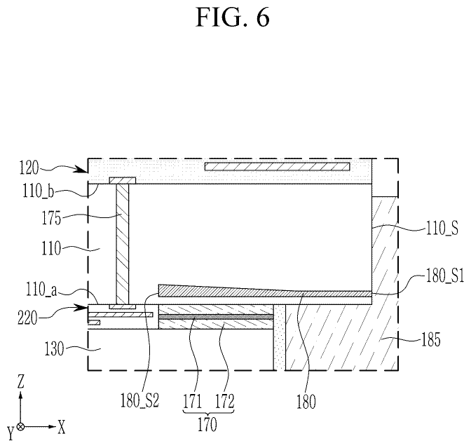

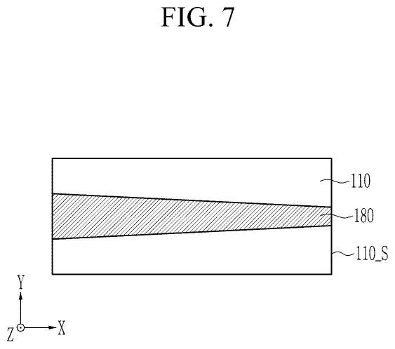

As illustrated in FIG. 3, on a cross-section formed by the second direction (the Y direction) and the third direction (the Z direction), the waveguide 180 may have an elliptical shape. However, example embodiments of the present disclosure are not limited thereto, and a cross-sectional shape of the waveguide 180 may be variously changed. For example, on the cross-section formed by the second direction (the Y direction) and the third direction (the Z direction), the waveguide 180 may have a circular shape, a polygonal shape, a rounded quadrangle shape, or the like. A width W along the second direction (the Y direction) of the waveguide 180 may be about 300 nm to about 1000 nm, but example embodiments of the present disclosure are not limited thereto. For example, the width W along the second direction (the Y direction) of the waveguide 180 may be about 400 nm to about 800 nm. A thickness TH along the third direction (the Z direction) of the waveguide 180 may be about 300 nm to about 1000 nm, but example embodiments of the present disclosure are not limited thereto. For example, the thickness TH along the third direction (the Z direction) of the waveguide 180 may be about 400 nm to about 800 nm. In this range, an optical signal transferred from the outside of the semiconductor package may be effectively transferred through the waveguide 180. In an example embodiment, the width W along the second direction (the Y direction) and the thickness TH along the third direction (the Z direction) of the waveguide 180 may be constant, but example embodiments of the present disclosure are not limited thereto. For example, the width W along the second direction (the Y direction) and/or the thickness TH along the third direction (the Z direction) of the waveguide 180 may include a portion that increases or decreases as the waveguide 180 moves away from the side surface 110_S of the substrate 110. A description thereof will be given later with reference to FIG. 6 and FIG. 7.

In an example embodiment, the waveguide 180 may include a first side surface 180_S1 and a second side surface 180_S2 opposite to the first side surface 180_S1. The first side surface 180_S1 of the waveguide 180 may be aligned with the side surface 110_S of the substrate 110. That is, one end portion of the waveguide 180 may be aligned with the side surface 110_S of the substrate 110. The first side surface 180_S1 of the waveguide 180 may be disposed at one end of the substrate 110. The second side surface 180_S2 of the waveguide 180 may be aligned with one side surface of a waveguide pattern 170 of the optical integrated circuit 130 that will be described later, but example embodiments of the present disclosure are not limited thereto.

In an example embodiment, the waveguide 180 may perform a function of implementing an optical path that confines light therein due to relatively high internal reflectance. For example, the waveguide 180 may perform a function of transferring light incident into the waveguide 180 from an interconnector 185 described later to the optical integrated circuit 130 described later.

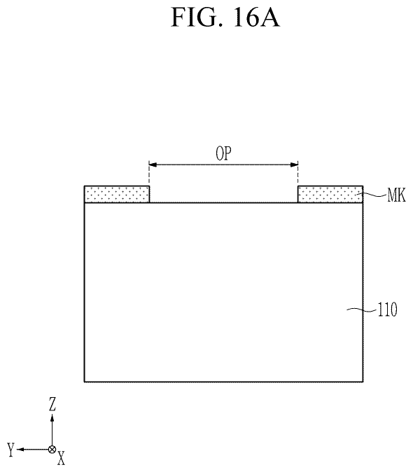

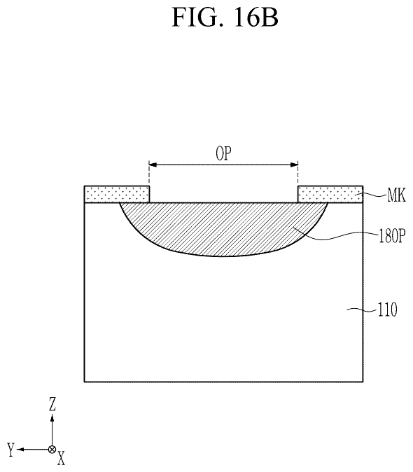

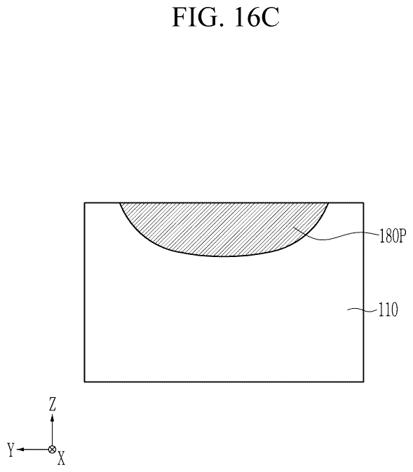

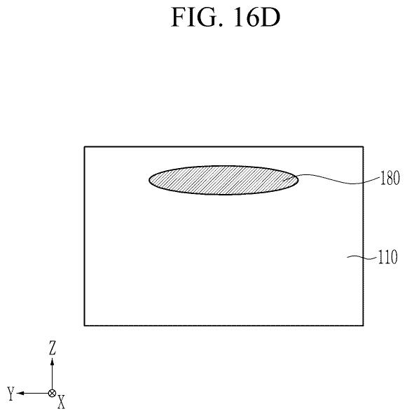

In an example embodiment, the waveguide 180 may include the same material as that of the substrate 110. For example, the waveguide 180 may include silica, but example embodiments of the present disclosure are not limited thereto. In an example embodiment, the waveguide 180 may include a first material and a second material different from the first material. For example, the first material may be a sodium ion (Na⁺), but example embodiments of the present disclosure are not limited thereto. A concentration of the first material of the waveguide 180 may be less than a concentration of the first material of the substrate 110. The second material may include a silver ion (Ag⁺) or a potassium ion (K⁺), but example embodiments of the present disclosure are not limited thereto. In some example embodiments, if the substrate 110 further includes the second material, a concentration of the second material of the waveguide 180 may be greater than a concentration of the second material of the substrate 110, but example embodiments of the present disclosure are not limited thereto. This may be due to a process characteristic of forming the waveguide 180 by replacing some materials constituting the substrate 110 with another material using an ion exchange method. For example, the waveguide 180 may be formed by replacing the first material of the substrate 110 with the second material using the ion exchange method. A detailed description thereof will be given later with reference to FIGS. 16A to 16D.

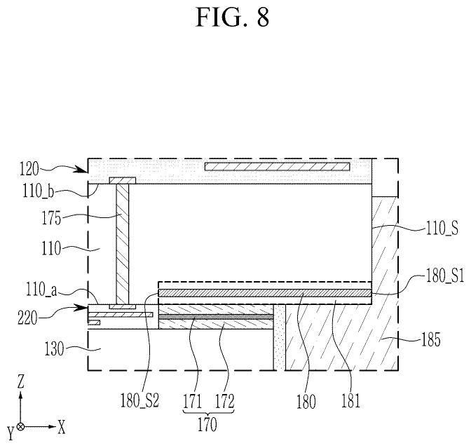

In an example embodiment, a refractive index of the waveguide 180 may be greater than a refractive index of the substrate 110. For example, the refractive index of the waveguide 180 may be about 1.45 to about 1.6, but example embodiments of the present disclosure are not limited thereto. In an example embodiment, a density of the waveguide 180 may be greater than a density of the substrate 110, but example embodiments of the present disclosure are not limited thereto. Accordingly, the waveguide 180 may perform a function of a core layer for implementing an optical path, and a portion of the substrate 110 surrounding the waveguide 180 may perform a function of a cladding layer. That is, the waveguide 180 may have a density and a refractive index different from those of the portion of the substrate 110 surrounding the waveguide 180, so that light incident into the waveguide 180 is completely (e.g., substantially entirely) reflected to implement the optical path. However, example embodiments of the present disclosure are not limited thereto, and the semiconductor package according to some example embodiments may further include a cladding layer 181 of FIG. 8 surrounding the waveguide 180. A description thereof will be given later with reference to FIG. 8.

The waveguide 180 may be optically connected to the optical integrated circuit 130 that will be described later. The waveguide 180 may optically connect the interconnector 185 that will be described later and the optical integrated circuit 130. An optical signal transferred from the interconnector 185 may be transferred to the optical integrated circuit 130 through the waveguide 180.

In some example embodiments, the waveguide 180 may be made of or include various materials. For example, the waveguide 180 may be a silicon waveguide, a silicon oxide waveguide, or a silicon nitride waveguide.

In some example embodiments, the waveguide 180 may further include an optical coupler for transmitting and receiving light incident from an external optical cable through the interconnector 185 that will be described later, but example embodiments of the present disclosure are not limited thereto.

The semiconductor package according to the example embodiment may further include the interconnector 185.

The interconnector 185 may be optically connected to an optical cable connected from the outside of the semiconductor package. The interconnector 185 may be connected to the optical cable to receive an optical signal from the optical cable. In an example embodiment, the interconnector 185 may be an optical coupler connector and/or an optical fiber connector connected to an external optical cable. The interconnector 185 may be a plug type, but example embodiments of the present disclosure are not limited thereto.

In an example embodiment, the interconnector 185 may be disposed at one side of the waveguide 180. For example, the interconnector 185 may be disposed on the first side surface 180_S1 of the waveguide 180. Additionally, the interconnector 185 may be disposed on the side surface 110_S of the substrate 110, but example embodiments of the present disclosure are not limited thereto.

The optical integrated circuit 130 may be mounted on the first surface 110_a of the substrate 110. The optical integrated circuit 130 may be disposed below the waveguide 180. The optical integrated circuit 130 may be optically connected to the waveguide 180. The optical integrated circuit 130 may be optically connected to an external optical cable through the waveguide 180. The optical integrated circuit 130 may receive an optical signal from the external optical cable. Additionally, the optical integrated circuit 130 may be electrically connected to the electronic integrated circuit 140 that will be described later. At least a portion of the optical integrated circuit 130 may overlap the waveguide 180 in the third direction (the Z direction).

In an example embodiment, the optical integrated circuit 130 may be a photonic integrated circuit (PIC). The optical integrated circuit 130 may receive the optical signal to convert the received optical signal into an analog electric signal (e.g., a current, a voltage, or the like), and may transfer the converted analog electric signal to the electronic integrated circuit 140. Additionally, the optical integrated circuit 130 may receive an electric signal to generate light, and may modulate the generated light to generate an optical signal. The generated optical signal may be transmitted to an external optical cable or the like through the waveguide 180.

In an example embodiment, the optical integrated circuit 130 may include the waveguide pattern 170 optically connected to the waveguide 180 and a first redistribution pattern 230 electrically connected to a first interconnection structure 115 that will be described later.

The waveguide pattern 170 may be disposed on the first surface 110_a of the substrate 110. The waveguide pattern 170 may be in contact with the first surface 110_a of the substrate 110, but example embodiments of the present disclosure are not limited thereto. The waveguide pattern 170 may be optically connected to the waveguide 180. The waveguide pattern 170 may perform a function of implementing an optical path that confines light therein due to relatively high internal reflectance. For example, the waveguide pattern 170 may be optically connected to the waveguide 180 to transfer external light applied from the waveguide 180 into the optical integrated circuit 130. The waveguide pattern 170 may overlap the waveguide 180 in the third direction (the Z direction). In an example embodiment, the waveguide pattern 170 may include a core pattern 171 and a cladding pattern 172 surrounding the core pattern 171.

The core pattern 171 may be disposed on the first surface 110_a of the substrate 110. In an example embodiment, the core pattern 171 may overlap the waveguide 180 in the third direction (the Z direction). The core pattern 171 may be disposed to be spaced apart from the waveguide 180 in the third direction (the Z direction). The core pattern 171 may be optically connected to the waveguide 180. For example, the core pattern 171 may be optically connected to the waveguide 180 through evanescent coupling.

The cladding pattern 172 may surround the core pattern 171. The cladding pattern 172 may be in contact with the first surface 110_a of the substrate 110, but example embodiments of the present disclosure are not limited thereto. The cladding pattern 172 may include a material having a refractive index lower than that of the core pattern 171. Accordingly, the waveguide pattern 170 may have a different refractive index from that of the cladding pattern 172 surrounding the waveguide pattern 170, so that light incident into the waveguide pattern 170 is completely (e.g., substantially entirely) reflected to implement an optical path.

The first redistribution pattern 230 may include a plurality of first redistribution layers 233 and a first redistribution insulating layer 231. The optical integrated circuit 130 may be electrically connected to a first interconnection bridge 113 that will be described later through the plurality of first redistribution layers 233. Additionally, the optical integrated circuit 130 may be electrically connected to a routing wire of the substrate 110 through the plurality of first redistribution layers 233. The first redistribution insulating layer 231 may protect and insulate the plurality of first redistribution layers 233. The first redistribution insulating layer 231 may include an insulating resin. The insulating resin may include a thermosetting resin such as an epoxy resin, a thermoplastic resin such as polyimide, or a resin (e.g., a photosensitive resin such as prepreg, Ajinomoto Build-up Film (ABF), Flame Retardant-4 (FR-4), Bismaleimide Triazine (BT), or a photo-imaging dielectric (PID)) impregnated with an inorganic filler and/or a glass fiber (a glass cloth or a glass fabric) in the above resins.

In an example embodiment, the optical integrated circuit 130 may have a chip-to-chip (C2C) structure bonded to the first interconnection structure 115 that will be described later by a wafer bonding method (e.g., a hybrid bonding method). For example, the plurality of first redistribution layers 233 of the optical integrated circuit 130 may be bonded in contact with the first interconnection bridge 113 of the first interconnection structure 115 to form a metal junction. However, example embodiments of the present disclosure are not limited thereto, and the optical integrated circuit 130 and the first interconnection structure 115 of the semiconductor package according to some example embodiments may be bonded by metal-to-metal direct bonding, solder bonding, or the like.

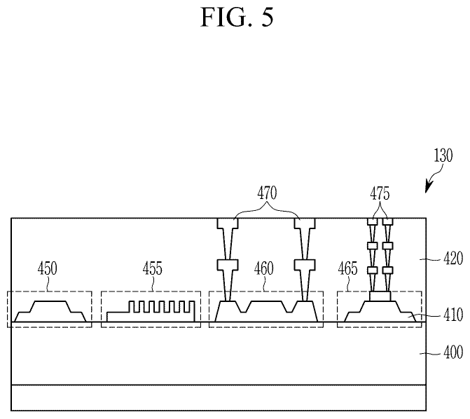

In an example embodiment, the optical integrated circuit 130 may further include various optical components. For example, the optical integrated circuit 130 may include a waveguide member 450 of FIG. 5, a grating coupler 455 of FIG. 5, an optical modulator 460 of FIG. 5, and a photodetector 465 of FIG. 5. The optical components of the optical integrated circuit 130 will be described in more detail with reference to FIG. 5.

In FIG. 1 and FIG. 2, the waveguide pattern 170 is illustrated as including the cladding pattern 172 and the core pattern 171, but example embodiments of the present disclosure are not limited thereto. As another example, the waveguide pattern 170 may include an optical fiber, a silicon waveguide, a silicon nitride waveguide, or the like, but example embodiments of the present disclosure are not limited thereto.

The waveguide 180 of the semiconductor package according to the example embodiment may be buried in the first surface 110_a of the substrate 110 (in the substrate 110 adjacent to the first surface 110_a), and the optical integrated circuit 130 may be mounted on the first surface 110_a of the substrate 110. Accordingly, a length of a path through which external light or the like transferred through the interconnector 185 is transferred to the optical integrated circuit 130 through the waveguide 180 may be reduced. Reliability of the semiconductor package according to the example embodiment may be improved.

The electronic integrated circuit (i.e., an EIC or an Electronic IC) 140 may be mounted on the first surface 110_a of the substrate 110. The electronic integrated circuit 140 may be disposed on the same plane as that of the optical integrated circuit 130. For example, the electronic integrated circuit 140 and the optical integrated circuit 130 may be disposed directly on the first surface 110_a of the substrate 110. The electronic integrated circuit 140 may be disposed to be spaced apart from the optical integrated circuit 130 in the first direction (the X direction) on the same plane. The electronic integrated circuit 140 may be electrically connected to the optical integrated circuit 130. Because the electronic integrated circuit 140 and the optical integrated circuit 130 are mounted on the first surface 110_a of the substrate 110, a length of a wire (e.g., the first interconnection bridge 113) connecting the electronic integrated circuit 140 and the optical integrated circuit 130 may be reduced. At least a portion of the electronic integrated circuit 140 may overlap the semiconductor chip 150 in the third direction (the Z direction). The electronic integrated circuit 140 may not overlap the waveguide 180 in the third direction (the Z direction), but example embodiments of the present disclosure are not limited thereto.

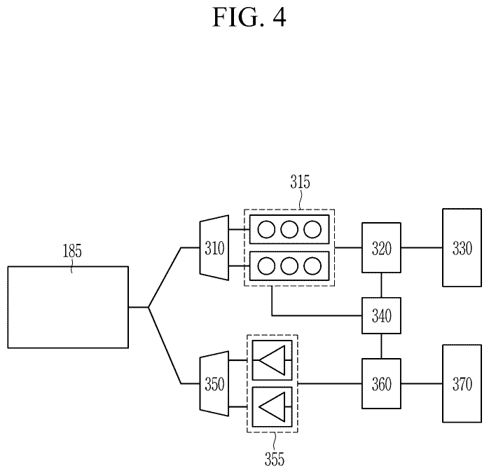

The electronic integrated circuit 140 may include various electronic components that control an operation of the optical integrated circuit 130. For example, the electronic integrated circuit 140 may include a transimpedance amplifier (TIA) 360 of FIG. 4, clock and data recovery (CDR), and one or more drivers (DRV). In an example embodiment, the transimpedance amplifier may be a transimpedance amplifier that may be implemented with one or more operational amplifiers. The transimpedance amplifier may amplify a current output of a photodetector or another type of a sensor of the optical integrated circuit 130 into a usable voltage. However, example embodiments of the present disclosure are not limited thereto, and the electronic integrated circuit 140 may include more electronic components.

The electronic integrated circuit 140 may be electrically connected to the substrate 110 and the semiconductor chip 150. For example, the electronic integrated circuit 140 may be electrically connected to the semiconductor chip 150 through the redistribution structure 120 using a conductive post 175 that will be described later.

The electronic integrated circuit 140 of the semiconductor package according to the example embodiment may include a second redistribution pattern 240. The second redistribution pattern 240 may include a plurality of second redistribution layers 243 and a second redistribution insulating layer 241. The electronic integrated circuit 140 may be electrically connected to the first interconnection bridge 113 that will be described later through the plurality of second redistribution layers 243. Additionally, the electronic integrated circuit 140 may be electrically connected to a routing wire of the substrate 110 through the plurality of second redistribution layers 243. The second redistribution insulating layer 241 may protect and insulate the plurality of second redistribution layers 243. The second redistribution insulating layer 241 may include an insulating resin. The insulating resin may include a thermosetting resin such as an epoxy resin, a thermoplastic resin such as polyimide, or a resin (e.g., a photosensitive resin such as prepreg, ABF, FR-4, BT, or a photo-imaging dielectric (PID)) impregnated with an inorganic filler and/or a glass fiber (a glass cloth or a glass fabric).

In an example embodiment, the electronic integrated circuit 140 may have a chip-to-chip (C2C) structure bonded to the first interconnection structure 115 that will be described later by a wafer bonding method (e.g., a hybrid bonding method). For example, the plurality of second redistribution layers 243 of the electronic integrated circuit 140 may be bonded in contact with the first interconnection bridge 113 of the first interconnection structure 115 to form a metal junction. However, example embodiments of the present disclosure are not limited thereto, and the electronic integrated circuit 140 and the first interconnection structure 115 of the semiconductor package according to some example embodiments may be bonded by metal-to-metal direct bonding, solder bonding, or the like.

The semiconductor package according to the example embodiment may include the first interconnection structure 115 including the first interconnection bridge 113 disposed within the substrate 110.

The first interconnection structure 115 may be buried in the substrate 110. For example, the first interconnection structure 115 may be buried in the first surface 110_a of the substrate 110 (e.g., may be buried in the substrate 110 adjacent to the first surface 110_a). A lower surface of the first interconnection structure 115 may be aligned with the first surface 110_a of the substrate 110. The first interconnection structure 115 may electrically connect the optical integrated circuit 130 and the electronic integrated circuit 140. The first interconnection structure 115 may overlap the optical integrated circuit 130 and the electronic integrated circuit 140 in the third direction (the Z direction).

In an example embodiment, the first interconnection structure 115 may include the first interconnection bridge 113 that electrically connects the optical integrated circuit 130 and the electronic integrated circuit 140.

The first interconnection bridge 113 may electrically connect the optical integrated circuit 130 and the electronic integrated circuit 140. The first interconnection bridge 113 may be an embedded multi-die interconnection bridge (EMIB). The first interconnection bridge 113 may form some of routing wires (not shown) of the substrate 110, but example embodiments of the present disclosure are not limited thereto. The first interconnection bridge 113 may be formed of multiple layers, but example embodiments of the present disclosure are not limited thereto. The first interconnection bridge 113 may include a conductive material. For example, the first interconnection bridge 113 may include a metallic material including copper (Cu), aluminum (Al), silver (Ag), tin (Sn), gold (Au), nickel (Ni), lead (Pb), titanium (Ti), or an alloy thereof.

In an example embodiment, each of the first interconnection structure 115 and the optical integrated circuit 130 may have a chip-to-chip (C2C) structure bonded by a wafer bonding method (e.g., a hybrid bonding method). That is, an upper surface of the optical integrated circuit 130 may be bonded to the lower surface of the first interconnection structure 115 by the hybrid bonding. The first interconnection bridge 113 of the first interconnection structure 115 may be bonded in contact with the plurality of first redistribution layers 233 of the optical integrated circuit 130 to form a metal junction. The first interconnection bridge 113 and the plurality of first redistribution layers 233 may be bonded to provide an electrical connection path between the optical integrated circuit 130 and the first interconnection structure 115.

In an example embodiment, the first interconnection structure 115 and the electronic integrated circuit 140 may have a chip-to-chip (C2C) structure bonded by a wafer bonding method (e.g., a hybrid bonding method). That is, an upper surface of the electronic integrated circuit 140 may be bonded to the lower surface of the first interconnection structure 115 by the hybrid bonding. The first interconnection bridge 113 of the first interconnection structure 115 may be bonded in contact with the plurality of second redistribution layers 243 of the electronic integrated circuit 140 to form a metal junction. The first interconnection bridge 113 and the plurality of second redistribution layers 243 may be bonded to provide an electrical connection path between the electronic integrated circuit 140 and the first interconnection structure 115.

Accordingly, the optical integrated circuit 130 and the electronic integrated circuit 140 may be electrically connected through the first interconnection structure 115. In this case, in an example embodiment, because the optical integrated circuit 130 and the electronic integrated circuit 140 are mounted directly on the first surface 110_a of the substrate 110, a length of the first interconnection bridge 113 for electrically connecting the optical integrated circuit 130 and the electronic integrated circuit 140 may be reduced. Accordingly, degree of integration and/or reliability of the semiconductor package may be improved.

In an example embodiment, the optical integrated circuit 130 and the electronic integrated circuit 140 are described as being bonded by the hybrid bonding with the first interconnection structure 115, but example embodiments of the present disclosure are not limited thereto. For example, the optical integrated circuit 130 and the electronic integrated circuit 140 of the semiconductor package according to some example embodiments may be bonded to the first interconnection structure 115 by metal-to-metal direct bonding, solder bonding, or the like.

The semiconductor package according to the example embodiment may further include the redistribution structure 120 disposed on the substrate 110.

The redistribution structure 120 may be disposed directly on the second surface 110_b of the substrate 110. The redistribution structure 120 may be electrically connected to a routing wire of the substrate 110.

In an example embodiment, the redistribution structure 120 may include a plurality of insulating layers 121, a plurality of redistribution layers 122, and a plurality of redistribution vias (not shown). In an example embodiment, the plurality of insulating layers 121 and the plurality of redistribution layers 122 of the redistribution structure 120 may be in contact with the second surface 110_b of the substrate 110. For example, the plurality of redistribution layers 122 of the redistribution structure 120 may be electrically connected by being in direct contact with routing wires (not shown) disposed within the substrate 110. However, example embodiments of the present disclosure are not limited thereto, and in an example embodiment, the redistribution structure 120 may have a chip shape, and may be electrically connected to the substrate 110 through a bump connected to the plurality of redistribution layers 122.

The plurality of insulating layers 121 may protect and insulate the plurality of redistribution layers 122. The substrate 110 may be disposed on lower surfaces of the plurality of insulating layers 121. The plurality of insulating layers 121 may include an insulating resin. The insulating resin may include a thermosetting resin such as an epoxy resin, a thermoplastic resin such as polyimide, or a resin (e.g., a photosensitive resin such as prepreg, ABF, FR-4, BT, or a photo-imaging dielectric (PID)) impregnated with an inorganic filler or/and a glass fiber (a glass cloth or a glass fabric). The plurality of insulating layers 121 may be stacked in a vertical direction. The vertical direction may mean a thickness direction (i.e., the third direction (the Z direction)) of the redistribution structure 120. A boundary between the plurality of insulating layers 121 may be unclear depending on a process, but example embodiments of the present disclosure are not limited thereto.

The plurality of redistribution layers 122 may be electrically connected to the substrate 110. For example, the plurality of redistribution layers 122 may be electrically connected to routing wires (not shown) disposed within the substrate 110. The plurality of redistribution layers 122 may be electrically connected to the semiconductor chip 150 and a memory chip 160 that will be described later. The plurality of redistribution layers 122 may include a conductive material. For example, each of the plurality of redistribution layers 122 may include a metallic material including copper (Cu), aluminum (Al), silver (Ag), tin (Sn), gold (Au), nickel (Ni), lead (Pb), titanium (Ti), or an alloy thereof.

The redistribution structure 120 of the semiconductor package according to the example embodiment may include a second interconnection structure 125 including a second interconnection bridge 123.

The second interconnection structure 125 may be disposed within the redistribution structure 120. The second interconnection structure 125 may overlap the semiconductor chip 150 and the memory chip 160 that will be described later in the third direction (the Z direction). In an example embodiment, the second interconnection structure 125 may include the second interconnection bridge 123 that electrically connects the semiconductor chip 150 and the memory chip 160 that will be described later.

The second interconnection bridge 123 may electrically connect the semiconductor chip 150 and the memory chip 160 that will be described later. The second interconnection bridge 123 may be an embedded multi-die interconnection bridge (EMIB). The second interconnection bridge 123 may include a conductive material. For example, the second interconnection bridge 123 may include a metallic material including copper (Cu), aluminum (Al), silver (Ag), tin (Sn), gold (Au), nickel (Ni), lead (Pb), titanium (Ti), or an alloy thereof.

The semiconductor chip 150 may be mounted on the second surface 110_b of the substrate 110. The semiconductor chip 150 may be disposed on the redistribution structure 120 disposed on the second surface 110_b of the substrate 110. The semiconductor chip 150 may overlap the electronic integrated circuit 140 in the third direction (the Z direction). The semiconductor chip 150 may overlap the optical integrated circuit 130 in the third direction (the Z direction), but example embodiments of the present disclosure are not limited thereto.

The semiconductor chip 150 may be electrically connected to the electronic integrated circuit 140. For example, the semiconductor chip 150 may pass through the redistribution structure 120 to be electrically connected to the electronic integrated circuit 140 through the conductive post 175 that will be described later. In this case, because the semiconductor chip 150 overlaps the electronic integrated circuit 140 in the third direction (the Z direction), a length of the conductive post 175 electrically connecting the semiconductor chip 150 and the electronic integrated circuit 140 may be reduced. Additionally, the semiconductor chip 150 may be electrically connected to the substrate 110, but example embodiments of the present disclosure are not limited thereto.

In an example embodiment, the semiconductor chip 150 may be an Application Specific Integrated Circuit (ASIC) chip, but example embodiments of the present disclosure are not limited thereto. As another example, the semiconductor chip 150 may include at least one of a central processing unit (CPU), a graphics processing unit (GPU), a memory, a controller, a codec, a sensor, or a communication chip.

In an example embodiment, the semiconductor chip 150 and the redistribution structure 120 may have a chip-to-chip (C2C) structure bonded by a wafer bonding method (e.g., a hybrid bonding method). That is, a lower surface of the semiconductor chip 150 may be bonded to an upper surface of the redistribution structure 120 by the hybrid bonding.

In an example embodiment, a portion of the lower surface of the semiconductor chip 150 adjacent to the redistribution structure 120 may be a bonding surface with the redistribution structure 120. Additionally, a portion of the upper surface of the redistribution structure 120 adjacent to the semiconductor chip 150 may be a bonding surface with the semiconductor chip 150. For example, the semiconductor chip 150 may include a first bonding insulating layer 151 and a first contact pad 153 disposed at a lower portion of the semiconductor chip 150. The first contact pad 153 and the redistribution layers 122 may be bonded in contact with each other to form a metal junction. The first bonding insulating layer 151 and the insulating layers 121 may be bonded to each other to form a bonding insulating layer. The first contact pad 153 and the redistribution layers 122 may be connected to each other to provide an electrical connection path between the redistribution structure 120 and the semiconductor chip 150.

In the example embodiment, it has been described that the semiconductor chip 150 and the redistribution structure 120 are bonded by the hybrid bonding, but example embodiments of the present disclosure are not limited thereto. For example, the semiconductor chip 150 and the redistribution structure 120 of the semiconductor package according to some example embodiments may be bonded by metal-to-metal direct bonding, solder bonding, or the like.

The memory chip 160 may be mounted on the second surface 110_b of the substrate 110. The memory chip 160 may be disposed on the redistribution structure 120 that is disposed on the second surface 110_b of the substrate 110. The memory chip 160 may overlap the optical integrated circuit 130 in the third direction (the Z direction), but example embodiments of the present disclosure are not limited thereto. The memory chip 160 may be disposed on the same plane as that of the semiconductor chip 150. For example, the memory chip 160 and the semiconductor chip 150 may be disposed directly on the upper surface of the redistribution structure 120. The memory chip 160 may be disposed to be spaced apart from the optical integrated circuit 130 in the first direction (the X direction) on the same plane.

The memory chip 160 may be electrically connected to the semiconductor chip 150. For example, the memory chip 160 may be electrically connected to the semiconductor chip 150 through the second interconnection bridge 123. In an example embodiment, because the memory chip 160 and the semiconductor chip 150 are disposed directly on the upper surface of the redistribution structure 120, a length of the second interconnection bridge 123 that electrically connects the memory chip 160 and the semiconductor chip 150 may be reduced. Additionally, the memory chip 160 may be electrically connected to the optical integrated circuit 130 through the conductive post 175, but example embodiments of the present disclosure are not limited thereto.

In an example embodiment, the memory chip 160 and the redistribution structure 120 may have a chip-to-chip (C2C) structure bonded by a wafer bonding method (e.g., a hybrid bonding method). That is, a lower surface of the memory chip 160 may be bonded to the upper surface of the redistribution structure 120 by the hybrid bonding.

In an example embodiment, a portion of the lower surface of the memory chip 160 adjacent to the redistribution structure 120 may be a bonding surface with the redistribution structure 120. Additionally, a portion of the upper surface of the redistribution structure 120 adjacent to the memory chip 160 may be a bonding surface with the memory chip 160. For example, the memory chip 160 may include a second bonding insulating layer 161 and a second contact pad 163 disposed at a lower portion of the memory chip 160. The second contact pad 163 and the redistribution layers 122 may be bonded in contact with each other to form a metal junction. The second bonding insulating layer 161 and the insulating layers 121 may be bonded to each other to form a bonding insulating layer. The first contact pad 153 and the redistribution layers 122 may be connected to each other to provide an electrical connection path between the redistribution structure 120 and the memory chip 160.

In the example embodiment, it has been described that the memory chip 160 and the redistribution structure 120 are bonded by the hybrid bonding, but example embodiments of the present disclosure are not limited thereto. For example, the memory chip 160 and the redistribution structure 120 of the semiconductor package according to some example embodiments may be bonded by metal-to-metal direct bonding, solder bonding, or the like.

A thickness of the semiconductor chip 150 in the third direction (the Z direction) of the semiconductor package according to an example embodiment may be greater than a thickness of the optical integrated circuit 130 in the third direction (the Z direction) and a thickness of the electronic integrated circuit 140 in the third direction (the Z direction). Additionally, a thickness of the memory chip 160 in the third direction (the Z direction) may be greater than a thickness of the optical integrated circuit 130 in the third direction (the Z direction) and a thickness of the electronic integrated circuit 140 in the third direction (the Z direction). In an example embodiment, the optical integrated circuit 130 and the electronic integrated circuit 140 may be mounted on the first surface 110_a of the substrate 110, and the semiconductor chip 150 and the memory chip 160 may be mounted on the redistribution structure 120 disposed on the second surface 110_b of the substrate 110, so that an entire thickness of the semiconductor package in the third direction (the Z direction) is reduced. That is, degree of integration of the semiconductor package according to the example embodiment may be improved.

The semiconductor package according to the example embodiment may further include the conductive post 175 penetrating the substrate 110. The conductive post 175 may extend in the third direction (the Z direction). In an example embodiment, the conductive post 175 may penetrate the substrate 110 to electrically connect the redistribution structure 120 and the optical integrated circuit 130 and electrically connect the redistribution structure 120 and the electronic integrated circuit 140.

The semiconductor package according to the example embodiment may further include a base substrate 100 disposed on the first surface 110_a of the substrate 110, a solder 192 disposed between the base substrate 100 and the substrate 110, a conductive pillar 195 disposed between the solder 192 and the substrate 110, and a molding layer 190 surrounding the conductive pillar 195.

The base substrate 100 may be a substrate for a package, and for example, the base substrate 100 may be a printed circuit board (PCB), a ceramic substrate, or the like. If the base substrate 100 is the printed circuit board (PCB), the base substrate 100 may be made of or include at least one material selected from a phenol resin, an epoxy resin, and polyimide.

The solder 192 may be disposed on the first surface 110_a of the substrate 110. The solder 192 may be disposed between the base substrate 110 and the substrate 110. The substrate 110 may be connected to the base substrate 100 through the solder 192. In an example embodiment, the solder 192 may surround the optical integrated circuit 130 and the electronic integrated circuit 140. For example, on a plane formed by the first direction (the X direction) and the second direction (the Y direction), the solder 192 may surround at least a portion of the optical integrated circuit 130 and at least a portion of the electronic integrated circuit 140.

The solder 192 may include a conductive material. For example, the solder 192 may include tin (Sn), silver (Ag), copper (Cu), manganese (Mn), lead (Pb), or an alloy thereof. For example, the solder 192 may include a solder ball or a solder bump.

The conductive pillar 195 may be disposed on the first surface 110_a of the substrate 110. The conductive pillar 195 may be electrically connected to a routing wire (not shown) of the substrate 110, the redistribution structure 120, and the like. The conductive pillar 195 may electrically connect the solder 192 and the substrate 110. In an example embodiment, the conductive pillar 195 may surround the optical integrated circuit 130 and the electronic integrated circuit 140. For example, on a plane formed by the first direction (the X direction) and the second direction (the Y direction), the conductive pillar 195 may surround at least a portion of the optical integrated circuit 130 and at least a portion of the electronic integrated circuit 140.

The molding layer 190 may mold the conductive pillar 195. Additionally, the molding layer 190 may mold the optical integrated circuit 130 and the electronic integrated circuit 140. The molding layer 190 may not surround the solder 192, but example embodiments of the present disclosure are not limited thereto.

Hereinafter, a semiconductor package according to an example embodiment will be described with reference to FIG. 4.

FIG. 4 is a schematic block diagram showing components of a semiconductor package according to an example embodiment.

In an example embodiment, the interconnector 185 may be an input/output port for an optical signal between an external optical cable and the semiconductor package. Hereinafter, each component will be described by dividing a case in which the optical signal is received through the interconnector 185 and a case in which the optical signal is transmitted through the interconnector 185.

Referring to FIG. 4, the optical signal received through the interconnector 185 may reach a plurality of photodetectors 355 through a demultiplexer (DEMUX) 350. The photodetector 355 may convert the optical signal into an analog electric signal. A transimpedance amplifier 360 may convert a current signal output from the photodetector 355 into a voltage signal. For example, the transimpedance amplifier may amplify a current output of the photodetector 355 or another type of a sensor of an optical integrated circuit 130 into a usable voltage. The converted electric signal may be output to the outside through an output driver 370.

If the electric signal is received at an input buffer 330, a light source element may emit light based on the received electric signal, and a modulator driver 320 may drive a plurality of optical modulators 315 to modulate light emitted from the light source element. Electronic components may be operated under a control of a controller 340. The modulated light may be transferred to the interconnector 185 through a multiplexer 310, and the optical signal may be transmitted.

It should be understood that the semiconductor package according to the example embodiment may include more optical components and more electronic components in addition to the components described above but only major components are introduced here for convenience of description.

In FIG. 4, the multiplexer 310, the plurality of optical modulators 315, the demultiplexer 350, and the plurality of photodetectors 355 may be optical components constituting the optical integrated circuit 130, and the transimpedance amplifier 360, the output driver 370, the input buffer 330, the modulator driver 320, and the controller 340 may be electronic components constituting an electronic integrated circuit 140.

However, example embodiments of the present disclosure are not limited thereto, and as another example, because the optical integrated circuit 130 is manufactured by a CMOS process, the optical integrated circuit 130 may include some of the electronic components as well as some of the optical components. The transimpedance amplifier 360, the output driver 370, the input buffer 330, the modulator driver 320, and the controller 340 may be classified according to a function performed by each component. This is not necessarily the same as a physical distinction. The electronic components of the electronic integrated circuit 140 may be configured as a transistor array, and the optical components of the optical integrated circuit 130 may include some of the transistor array.

Hereinafter, an optical integrated circuit of a semiconductor package according to an example embodiment will be described with reference to FIG. 5.

FIG. 5 is a cross-sectional view showing the optical integrated circuit of the semiconductor package according to the example embodiment.

Referring to FIG. 5, an optical integrated circuit 130 of the semiconductor package according to the example embodiment may include a silicon layer 410 and a silicon layer 410 on the buried oxide layer 400. The silicon layer 410 may include the waveguide member 450, the grating coupler 455, the optical modulator 460, and the photodetector 465.

The buried oxide (BOX) layer 400 may be disposed on a silicon-based member. The buried oxide layer 400 may be formed over an entire upper surface of the silicon-based member, or may be formed only at a portion thereof.

The silicon layer 410 may be disposed on the buried oxide layer 400. The silicon layer 410 may constitute optical components. For example, the silicon layer 410 may include an optical waveguide member 450, the grating coupler 455, the optical modulator 460, and the photodetector 465.

In an example embodiment, a process of forming the silicon layer 410 may form a patterned silicon layer 410 by forming a silicon material layer on the buried oxide layer 400 and patterning the silicon material layer by a lithography process, an etching process, or the like. A cladding layer 420 may be stacked on the silicon layer 410. Although not shown in the drawings, a nitride layer may be further disposed on the patterned silicon layer 410.

The waveguide member 450 may be optically connected to the optical components. The waveguide member 450 may perform a function of implementing an optical path that confines and transfers light within the optical integrated circuit 130. The waveguide member 450 may perform substantially the same function as that of the waveguide pattern 170 of FIG. 3. For example, the waveguide member 450 may include an optical fiber, a silicon waveguide member, a silicon nitride waveguide member, or the like. As another example, the waveguide member 450 may include a core layer and a plurality of cladding layers. The waveguide member 450 may be formed of a single structure or a plurality of structures.

The grating coupler 455 may be a medium that receives an optical signal transmitted from the outside or transmits an optical signal to the outside. The grating coupler 455 may be optically connected to the waveguide member 450. Although the grating coupler 455 is disclosed in the present example embodiment, it will be easily understood by those skilled in the art that an edge coupler may be used. If the edge coupler is used, light may not be vertically transmitted and received toward an upper surface of the waveguide 180, and may be horizontally transmitted and received through an edge thereof.

The optical modulator 460 may modulate light emitted from a light source element according to a signal to be transmitted to convert the modulated light into an optical signal having information. For example, the optical modulator 460 may be a phase modulator. In some example embodiments, the optical modulator 460 may be any one of a Mach-Zehnder modulator, a micro-ring modulator, an electro-absorption (EAM) modulator, an LN-Si hybrid optical modulator, or a Thin Film Lithium Niobate (TFLN) optical modulator, but example embodiments of the present disclosure are not limited thereto.

The photodetector 465 may generate and output an electric signal based on the received optical signal. For example, the photodetector 465 may be a positive-intrinsic-negative (PIN) structure including a germanium (Ge) area. Although not shown in FIG. 5, the waveguide 180 may further include a ring resonator. The ring resonator may be an element that filters a signal of a desired wavelength from an optical signal transferred through the waveguide member 450. Example embodiments of the present disclosure are not limited to the optical components described above, and the waveguide 180 may further include a switch, a splitter, a heater, or the like in addition to the components described above.

In an example embodiment, optical components may be classified into a passive component and an active component. The waveguide member 450 and the grating coupler 455 may belong to the passive component, and the optical modulator 460 and the photodetector 465 may belong to the active component. In order to electrically connect active components to electronic components, the active components may be electrically connected to contact terminals 470 and 475 that penetrate the clad layer 420 to be exposed on an upper surface thereof. Various structures for electrically connecting the active components to the electronic components of the electronic integrated circuit 140 may be used, and example embodiments of the present disclosure are not limited to structures of the contact terminals 470 and 475 of the present embodiment.

An example of the optical integrated circuit 130 including the optical components has been described with reference to FIG. 5, but example embodiments of the present disclosure are not limited to the above-described structure.

Hereinafter, semiconductor packages according to some example embodiments will be described with reference to FIGS. 6 to 11.

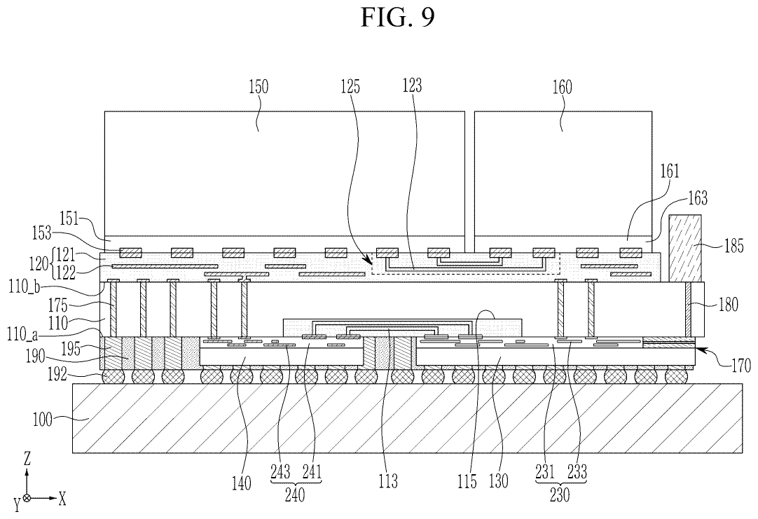

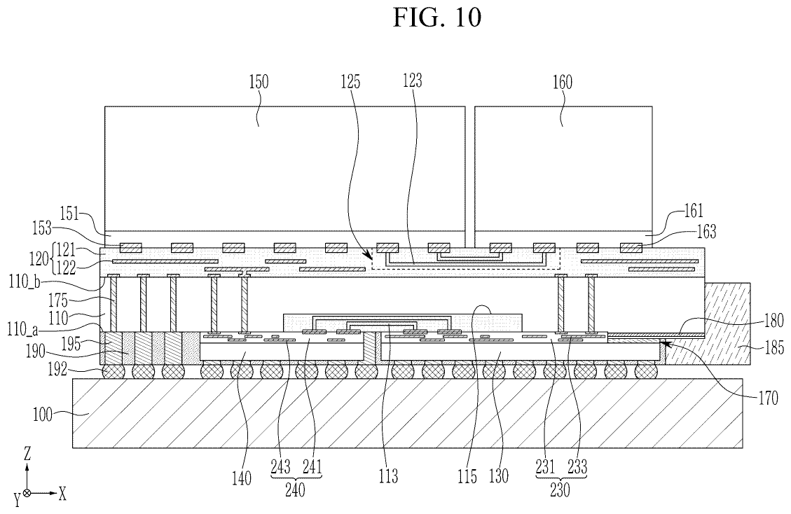

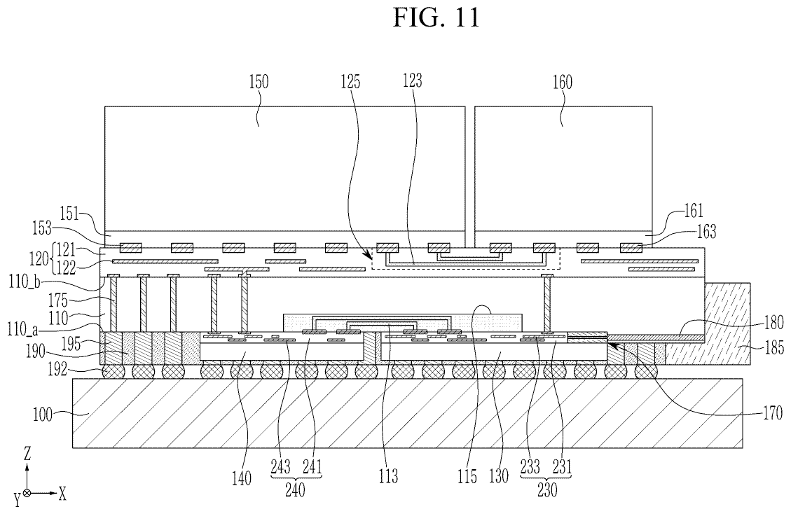

FIG. 6 is a cross-sectional view showing the semiconductor package according to an example embodiment and corresponding to the area S1 of FIG. 1. FIG. 7 is a plan view showing a waveguide of the semiconductor package according to the example embodiment of FIG. 6. FIG. 8 is a cross-sectional view showing the semiconductor package according to an example embodiment and corresponding to the area S1 of FIG. 1. FIGS. 9 to 11 are cross-sectional views showing the semiconductor packages according to some example embodiments. Because the example embodiments shown in FIGS. 6 to 11 have the same portion as that of the embodiment shown in FIGS. 1 to 5, a description thereof will be omitted and a difference between the example embodiments shown in FIGS. 6 to 11 and the example embodiments shown in FIGS. 1 to 5 will be mainly described.

Referring to FIG. 6, a waveguide 180 of the semiconductor package according to an example embodiment may include a portion in which a thickness along the third direction (the Z direction) increases as a distance between the portion and a side surface 110_S of a substrate 110 increases. The thickness along the third direction (the Z direction) of the waveguide 180 may include a portion that increases as it moves away from a side surface 110_S of the substrate 110. The thickness along the third direction (the Z direction) of the waveguide 180 may include a portion that increases as it moves away from an interconnector 185. Accordingly, external light may be easily transferred from the waveguide 180 to a waveguide pattern 170. However, example embodiments of the present disclosure are not limited thereto. In some example embodiments, the thickness along the third direction (the Z direction) of the waveguide 180 may include a portion that decreases as it moves away from the side surface 110_S of the substrate 110.

Referring to FIG. 7, the waveguide 180 of the semiconductor package according to an example embodiment may include a portion in which a width along the second direction (the Y direction) increases as a distance between the portion and the side surface 110_S of the substrate 110 increases. The width along the second direction (the Y direction) of the waveguide 180 may include a portion that increases as it moves away from the side surface 110_S of the substrate 110. For example, the width along the second direction (the Y direction) of the waveguide 180 may increase as it moves away from the side surface 110_S of the substrate 110, but example embodiments of the present disclosure are not limited thereto. The width along the second direction (the Y direction) of the waveguide 180 may include a portion that increases as it moves away from the interconnector 185. Accordingly, external light may be easily transferred from the waveguide 180 to the waveguide pattern 170. However, example embodiments of the present disclosure are not limited thereto. In some example embodiments, the width along the second direction (the Y direction) of the waveguide 180 may include a portion that decreases as it moves away from the side surface 110_S of the substrate 110.

Referring to FIG. 8, the semiconductor package according to an example embodiment may further include a cladding layer 181 surrounding a waveguide 180.

The cladding layer 181 may surround the waveguide 180. The cladding layer 181 may be buried in a substrate 110. For example, the cladding layer 181 may be buried in a first surface 110_a of a substrate 110. A lower surface of the cladding layer 181 may be aligned with the first surface 110_a of the substrate 110, but example embodiments of the present disclosure are not limited thereto. The lower surface of the cladding layer 181 may be in contact with an optical integrated circuit 130. For example, the lower surface of the cladding layer 181 may be in contact with a cladding pattern 172 of the optical integrated circuit 130, but example embodiments of the present disclosure are not limited thereto.

In some example embodiments, the cladding layer 181 may include silica. The cladding layer 181 may include a first material. For example, the first material may be a sodium ion (Na⁺), but example embodiments of the present disclosure are not limited thereto. That is, the cladding layer 181 may be a glass substrate including the sodium ion (Na⁺). In this case, a concentration of the first material of the cladding layer 181 may be different from a concentration of a first material of the substrate 110. For example, the concentration of the first material of the cladding layer 181 may be greater than the concentration of the first material of the substrate 110. In some example embodiments, the concentration of the first material of the cladding layer 181 may be greater than a concentration of a first material of the waveguide 180. A refractive index of the cladding layer 181 may be less than a refractive index of the waveguide 180. This may be due to a process characteristic of forming the waveguide 180 using an ion exchange method after the first material is added into the substrate 110 in a process of forming the waveguide 180 of the semiconductor package according to some example embodiments. However, example embodiments of the present disclosure are not limited thereto, and the cladding layer 181 may include various materials having a refractive index lower than the refractive index of the waveguide 180.

Referring to FIG. 9, a waveguide 180 of the semiconductor package according to an example embodiment may extend in the third direction (the Z direction). For example, the waveguide 180 may extend in the third direction (the Z direction) from a second surface 110_b of a substrate 110 to a first surface 110_a of the substrate 110. The waveguide 180 may penetrate the substrate 110. An interconnector 185 may be disposed on an upper surface of the waveguide 180. The interconnector 185 may be disposed on the second surface 110_b of the substrate 110.

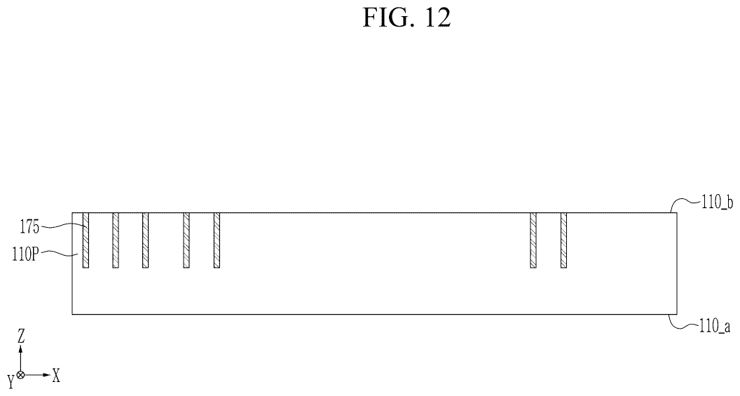

Referring to FIG. 10 and FIG. 11, for example, a substrate 110 of the semiconductor package according to some example embodiments may include a portion protruding toward a base substrate 100, and a waveguide 180 may be buried in the portion of the substrate 110 protruding toward the base substrate 100. In these example embodiments, a lower surface of the waveguide 180 may be disposed at a level lower than that of a first surface 110_a of the substrate 110 (e.g., non-protruding portion of the first surface 110_a of the substrate 110). The lower surface of the waveguide 180 may be disposed closer to an upper surface of the base substrate 100 than to the first surface 110_a of the substrate 110 (e.g., non-protruding portion of the first surface 110_a of the substrate 110). An upper surface of the waveguide 180 may be disposed at a level lower than that of the first surface 110_a of the substrate 110 (e.g., non-protruding portion of the first surface 110_a of the substrate 110), but example embodiments of the present disclosure are not limited thereto.

In these example embodiments, a waveguide pattern 170 of an optical integrated circuit 130 may be optically connected to the waveguide 180. For example, as illustrated in FIG. 10, the waveguide pattern 170 may overlap the waveguide 180 in the third direction (the Z direction). In this case, a core pattern of the waveguide pattern 170 may be disposed apart from the waveguide 180 in the third direction (the Z direction). The core pattern may be optically connected to the waveguide 180 through evanescent coupling. As another example, as illustrated in FIG. 11, the waveguide pattern 170 may be disposed at one side along the first direction (the X direction) of the waveguide 180. In this case, a side surface of the waveguide pattern 170 may be in contact with the waveguide 180.

Hereinafter, a manufacturing method of the semiconductor package according to an example embodiment will be described with reference to FIGS. 12 to 21.

FIGS. 12 to 21 are cross-sectional views showing the manufacturing method of the semiconductor package according to an example embodiment. FIGS. 16A to 16D are enlarged cross-sectional views illustrating a manufacturing method of the waveguide of the semiconductor package according to an example embodiment.

Referring to FIG. 12, the conductive post 175 may be formed within a preliminary substrate 110P.

The preliminary substrate 110P may be a glass substrate. The preliminary substrate 110P may include silica. For example, the preliminary substrate 110P may include a silicon-based material such as glass or silicon oxide, an organic material, another material such as aluminum oxide, or any combination of these materials. In an example embodiment, the preliminary substrate 110P may include a first material. For example, the first material may be a sodium ion (Na⁺), but example embodiments of the present disclosure are not limited thereto. That is, the preliminary substrate 110P may be the glass substrate including the sodium ion (Na⁺).

The preliminary substrate 110P may include a first surface 110_a and a second surface 110_b that are opposite to each other. The first surface 110_a and the second surface 110_b of the preliminary substrate 110P may be formed of a plane parallel to a first direction (e.g., an X direction) and a second direction (e.g., a Y direction) intersecting the first direction (the X direction). The first surface 110_a of the preliminary substrate 110P may be a surface opposite to the second surface 110_b in a third direction (e.g., a Z direction). The first surface 110_a of the preliminary substrate 110P may be referred to as a lower surface of the preliminary substrate 110P, and the second surface 110_b of the preliminary substrate 110P may be referred to as an upper surface of the preliminary substrate 110P. The third direction (the Z direction) may mean a vertical direction that is perpendicular to the first surface 110_a of the preliminary substrate 110P.

The conductive post 175 may be formed within the preliminary substrate 110P. For example, after a recess is formed by removing at least a portion of the preliminary substrate 110P, a conductive material may be formed within the recess to form the conductive post 175. The conductive post 175 may extend in the third direction (the Z direction).

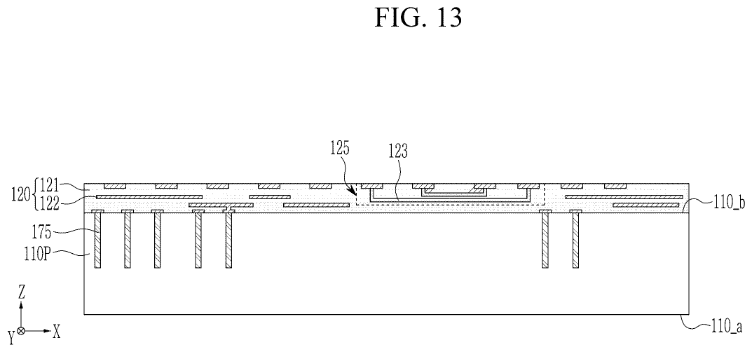

Referring to FIG. 13, the redistribution structure 120 may be formed on the second surface 110_b of the preliminary substrate 110P. The redistribution structure 120 may be disposed on the second surface 110_b of the preliminary substrate 110P. The redistribution structure 120 may be disposed directly on the second surface 110_b of the preliminary substrate 110P. The redistribution structure 120 may be formed by alternately forming the plurality of redistribution layers 122 and the plurality of insulating layers 121. The redistribution structure 120 may be electrically connected to the conductive post 175. In an example embodiment, during a process of forming the redistribution structure 120, the second interconnection structure 125 including the second interconnection bridge 123 may be formed together.

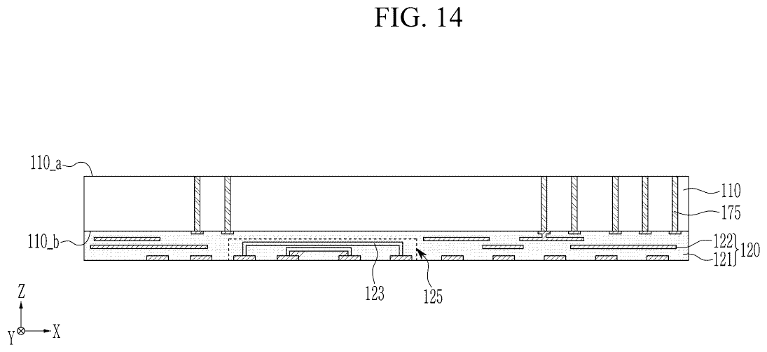

Referring to FIG. 14, the semiconductor package may be flipped, and at least a portion of the preliminary substrate 110P may be removed to form the substrate 110. For example, at least a portion of the preliminary substrate 110P may be removed using chemical mechanical polishing (CMP). Accordingly, the conductive post 175 may be exposed.

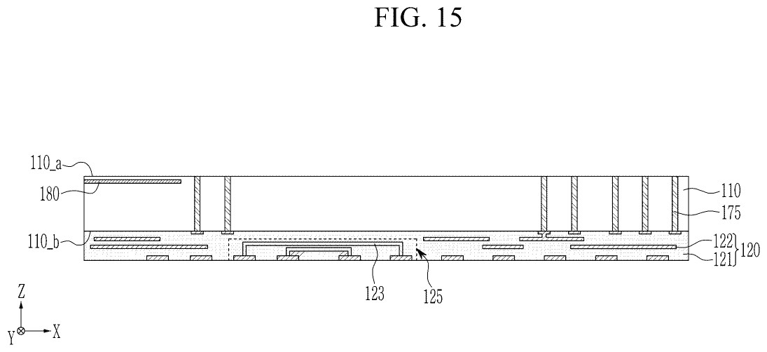

Referring to FIG. 15 and FIGS. 16A to 16D, the waveguide 180 buried in the substrate 110 adjacent to the first surface 110_a may be formed. The waveguide 180 may be formed at one end portion of the substrate 110. The waveguide 180 may be buried in the substrate 110. For example, the waveguide 180 may be buried in the first surface 110_a of the substrate 110. The waveguide 180 may be surrounded by the substrate 110. Accordingly, a lower surface of the waveguide 180 may be disposed closer to a lower surface of the redistribution structure 120 than to the first surface 110_a of the substrate 110.

For example, first, as shown in FIG. 16A, a mask pattern MK having an open portion OP may be formed on the substrate 110. The mask pattern MK may be a hard mask pattern, but example embodiments of the present disclosure are not limited thereto.

Next, as illustrated in FIG. 16B, a first material present within the substrate 110 may be replaced with a second material using an ion exchange method. A preliminary waveguide 180P may be formed by replacing at least a portion of the first material present in a portion of the substrate 110 exposed by the open portion OP with the second material. In this case, because the ion exchange method is used, the first material may be replaced with the second material at an area larger than an area of the open portion OP. In an example embodiment, a width along the second direction (the Y direction) of the open portion OP may be smaller than a maximum width along the second direction (the Y direction) of the preliminary waveguide 180P, but example embodiments of the present disclosure are not limited thereto. The first material may be a sodium ion (Na⁺) and the second material may include a silver ion (Ag⁺) or a potassium ion (K⁺), but example embodiments of the present disclosure are not limited thereto.

Accordingly, the preliminary waveguide 180P may include the same material as that of the substrate 110. For example, the preliminary waveguide 180P may include silica, but example embodiments of the present disclosure are not limited thereto. The waveguide 180 may include a first material and a second material different from the first material. A concentration of the first material of the preliminary waveguide 180P may be less than a concentration of the first material of the substrate 110. In some example embodiments, if the substrate 110 further includes the second material, a concentration of the second material of the preliminary waveguide 180P may be greater than a concentration of the second material of the substrate 110, but example embodiments of the present disclosure are not limited thereto. In an example embodiment, a refractive index of the preliminary waveguide 180P may be greater than a refractive index of the substrate 110. For example, the refractive index of the preliminary waveguide 180P may be about 1.45 to about 1.6, but example embodiments of the present disclosure are not limited thereto. In an example embodiment, a density of the preliminary waveguide 180P may be greater than a density of the substrate 110, but example embodiments of the present disclosure are not limited thereto.

Next, as illustrated in FIG. 16C, the mask pattern MK may be removed on the substrate 110. Next, as illustrated in FIG. 16D, the second material present in at least a portion of the preliminary waveguide 180P may be replaced back with the first material using an ion exchange method. For example, the waveguide 180 may be formed by replacing at least a portion of the second material disposed at an upper portion of the preliminary waveguide 180P with the first material. Accordingly, the waveguide 180 may be buried in the substrate 110. The waveguide 180 may be surrounded by the substrate 110.

In an example embodiment, on a cross-section formed by the second direction (the Y direction) and the third direction (the Z direction), the waveguide 180 may have an elliptical shape. However, example embodiments of the present disclosure are not limited thereto, and a cross-sectional shape of the waveguide 180 may be variously changed. For example, on the cross-section formed by the second direction (the Y direction) and the third direction (the Z direction), the waveguide 180 may have a circular shape, a polygonal shape, a rounded quadrangle shape, or the like. A width along the second direction (the Y direction) of the waveguide 180 may be about 300 nm to about 1000 nm, but example embodiments of the present disclosure are not limited thereto. For example, the width along the second direction (the Y direction) of the waveguide 180 may be about 400 nm to about 800 nm. A thickness along the third direction (the Z direction) of the waveguide 180 may be about 300 nm to about 1000 nm, but example embodiments of the present disclosure are not limited thereto. For example, the thickness along the third direction (the Z direction) of the waveguide 180 may be about 400 nm to about 800 nm. In this range, an optical signal transferred from the outside of the semiconductor package may be effectively transferred through the waveguide 180.

In an example embodiment, the preliminary waveguide 180P may perform a function of a core layer for implementing an optical path, and a portion of the substrate 110 surrounding the preliminary waveguide 180P may perform a function of a cladding layer. That is, the preliminary waveguide 180P may have a density and a refractive index different from those of the portion of the substrate 110 surrounding the preliminary waveguide 180P, so that light incident into the preliminary waveguide 180P is completely (e.g., substantially entirely) reflected to implement the optical path.

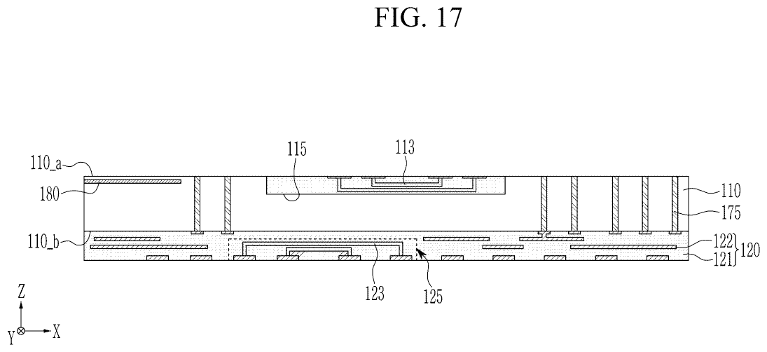

Referring to FIG. 17, the first interconnection structure 115 that is buried within a portion of the substrate 110 adjacent to the first surface 110_a and includes the first interconnection bridge 113 may be formed. A lower surface of the first interconnection structure 115 may be aligned with the first surface 110_a of the substrate 110. The first interconnection structure 115 may electrically connect the optical integrated circuit 130 and the electronic integrated circuit 140.

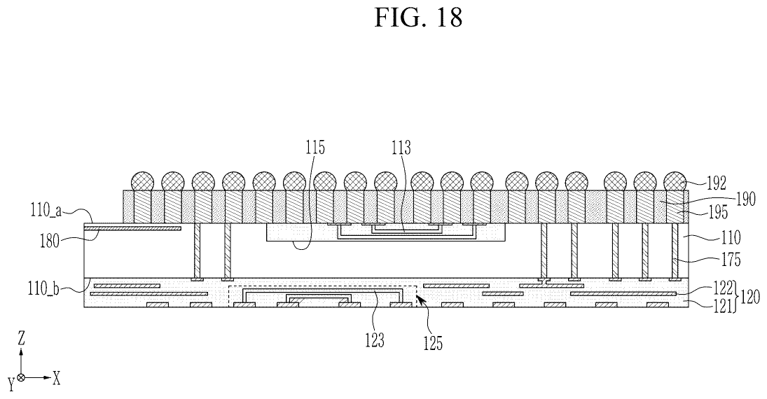

Referring to FIG. 18, the conductive pillar 195, the molding layer 190, and the solder 192 may be formed on the first surface 110_a of the substrate 110. For example, after the conductive pillar 195 is formed on the first surface 110_a of the substrate 110, the molding layer 190 surrounding the conductive pillar 195 may be formed. In an example embodiment, an upper surface of the molding layer 190 may be disposed at substantially the same level as that of an upper surface of the conductive pillar 195. The upper surface of the molding layer 190 and the upper surface of the conductive pillar 195 may be disposed at substantially the same distance from the first surface 110_a of the substrate 110, but example embodiments of the present disclosure are not limited thereto. Next, the solder 192 may be formed on the upper surface of the conductive pillar 195. The solder 192 may include a conductive material. For example, the solder 192 may include tin (Sn), silver (Ag), copper (Cu), manganese (Mn), lead (Pb), or an alloy thereof. For example, the solder 192 may include a solder ball or a solder bump.

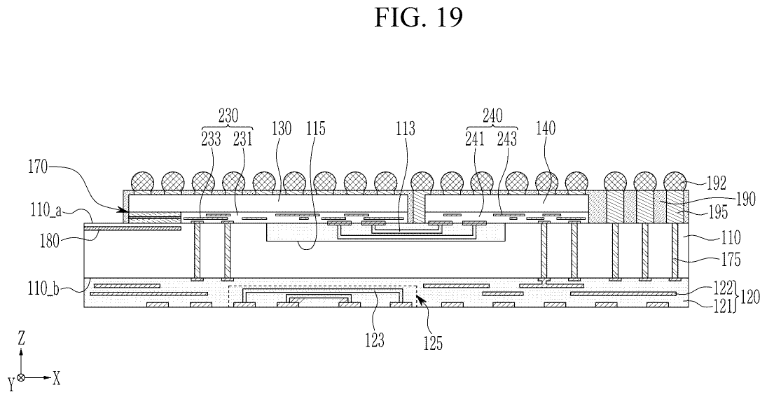

Referring to FIG. 19, the optical integrated circuit 130 and the electronic integrated circuit 140 may be formed above the first surface 110_a of the substrate 110. The optical integrated circuit 130 and the electronic integrated circuit 140 may be disposed directly on the first surface 110_a of the substrate 110. The optical integrated circuit 130 and the electronic integrated circuit 140 may be disposed to be spaced apart from each other in the first direction (the X direction), but example embodiments of the present disclosure are not limited thereto. The optical integrated circuit 130 may overlap the waveguide 180 in the third direction (the Z direction). The optical integrated circuit 130 and the electronic integrated circuit 140 may have a chip-to-chip (C2C) structure bonded to the first interconnection structure 115 by a wafer bonding method (e.g., a hybrid bonding method). A description thereof is given in the embodiments of FIGS. 1 to 5, so that it will be omitted.

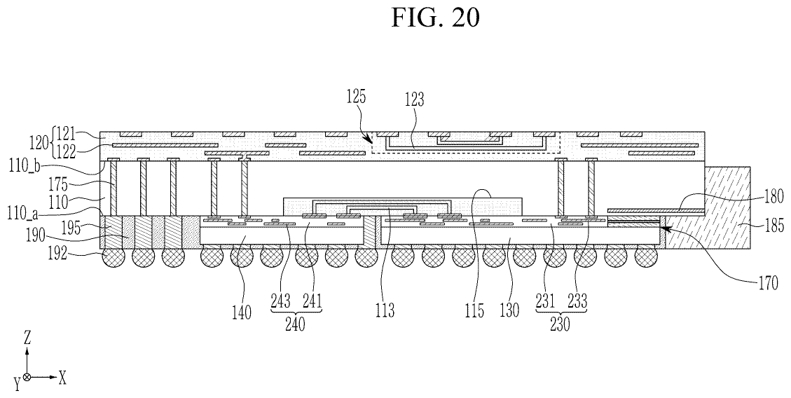

Referring to FIG. 20, the semiconductor package may be flipped, and the interconnector 185 may be formed on a side surface of the waveguide 180. The interconnector 185 may be optically connected to an optical cable connected from the outside of the semiconductor package. The interconnector 185 may be connected to the optical cable to receive an optical signal from the optical cable. In an example embodiment, the interconnector 185 may be an optical coupler connector or an optical fiber connector connected to an external optical cable. The interconnector 185 may be a plug type, but example embodiments of the present disclosure are not limited thereto.

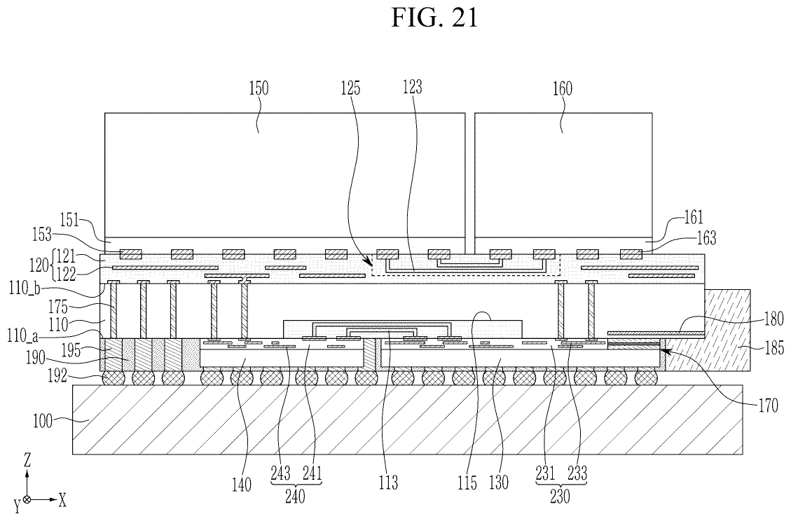

Referring to FIG. 21, the semiconductor chip 150 and the memory chip 160 may be formed on an upper surface of the redistribution structure 120 and the base substrate 100 electrically connected to the solder 192 may be formed to form the semiconductor package according to the example embodiment.

While this disclosure has been described in connection with what is presently considered to be practical example embodiments, it should be understood that the disclosure is not limited to the disclosed example embodiments, but, on the contrary, is intended to cover various modifications and equivalent arrangements included within the spirit and scope of the appended claims.

What is claimed is:

1. A semiconductor package comprising:
a substrate includes a first surface and a second surface opposite to the first surface;
a waveguide buried in the substrate;
an optical integrated circuit on the first surface of the substrate, the optical integrated circuit optically connected to the waveguide;
an electronic integrated circuit on the first surface of the substrate, the electronic integrated circuit electrically connected to the optical integrated circuit; and
a semiconductor chip on the second surface of the substrate.

2. The semiconductor package of claim 1, wherein the waveguide is buried in the substrate such that the waveguide is adjacent to the first surface and surrounded by the substrate.

3. The semiconductor package of claim 2, wherein one end portion of the waveguide is aligned with a side surface of the substrate.

4. The semiconductor package of claim 1, wherein each of the substrate and the waveguide includes a first material, and a concentration of the first material of the waveguide is less than a concentration of the first material of the substrate.

5. The semiconductor package of claim 4, wherein each of the substrate and the waveguide includes silica, and the first material includes a sodium ion.

6. The semiconductor package of claim 5, wherein the waveguide further includes a silver ion or a potassium ion.

7. The semiconductor package of claim 4, wherein a refractive index of the waveguide is 1.45 to 1.6, and a refractive index of the substrate is 1.44 to 1.46.

8. The semiconductor package of claim 4, wherein a width of the waveguide is 300 nm to 1000 nm.

9. The semiconductor package of claim 1, wherein at least a portion of the waveguide overlaps the optical integrated circuit in a vertical direction.

10. The semiconductor package of claim 9, wherein at least a portion of the electronic integrated circuit overlaps the semiconductor chip in the vertical direction.

11. The semiconductor package of claim 1, further comprising:
a solder on the first surface of the substrate; and
a conductive pillar between the solder and the substrate,
wherein the solder surrounds the optical integrated circuit and the electronic integrated circuit on a plane.

12. The semiconductor package of claim 1, wherein the optical integrated circuit includes a redistribution pattern electrically connected to the electronic integrated circuit and a waveguide pattern, the waveguide pattern including a core pattern and a cladding pattern, the core pattern optically connected to the waveguide, the cladding pattern surrounding the core pattern and spaced apart from the waveguide.

13. The semiconductor package of claim 1, further comprising:
an interconnector on a side surface of the waveguide and optically connected to the waveguide.

14. The semiconductor package of claim 13, wherein the waveguide includes a portion whose thickness increases as the waveguide moves away from the interconnector.

15. The semiconductor package of claim 1, further comprising:
a cladding layer surrounding the waveguide, the cladding layer including a first material,
wherein the waveguide includes the first material, and a concentration of the first material of the cladding layer is greater than a concentration of the first material of the waveguide.

16. A semiconductor package comprising:
a substrate includes a first surface and a second surface opposite to the first surface, the substrate including a first material;
an interconnector on a side surface of the substrate;
a waveguide buried in the substrate adjacent to the first surface, the waveguide optically connected to the interconnector, the waveguide including the first material;
an optical integrated circuit on the first surface of the substrate, the optical integrated circuit optically connected to the waveguide;
an electronic integrated circuit on the first surface of the substrate, the electronic integrated circuit electrically connected to the optical integrated circuit; and
a semiconductor chip on the second surface of the substrate,
wherein a concentration of the first material of the waveguide is less than a concentration of the first material of the substrate.

17. The semiconductor package of claim 16, wherein the waveguide further includes a silver ion or a potassium ion.

18. The semiconductor package of claim 16, wherein the waveguide extends in a first direction from the side surface of the substrate.

19. The semiconductor package of claim 18, wherein the optical integrated circuit includes a redistribution pattern electrically connected to the electronic integrated circuit and a waveguide pattern, the waveguide pattern optically connected to the waveguide, extending in the first direction, and overlapping the waveguide in a vertical direction.

20. A semiconductor package comprising:
a substrate includes a first surface and a second surface opposite to the first surface;
an interconnector on a side surface of the substrate;
a waveguide buried in the substrate adjacent to the first surface, the waveguide optically connected to the interconnector;
an optical integrated circuit on the first surface of the substrate, the optical integrated circuit optically connected to the waveguide;
an electronic integrated circuit on the first surface of the substrate, the electronic integrated circuit electrically connected to the optical integrated circuit;
a redistribution structure on the second surface of the substrate;
a semiconductor chip on the redistribution structure; and
a memory chip on the redistribution structure, the memory chip electrically connected to the semiconductor chip,
wherein the waveguide overlaps the optical integrated circuit in a vertical direction, and the electronic integrated circuit overlaps the semiconductor chip in the vertical direction.
